(19) United States
(12) Patent Application Publication
(10) Pub. No.: US 2016/0126176 A1
(43) Pub. Date: May 5, 2016

(54) PACKAGE SUBSTRATE, PACKAGE STRUCTURE AND FABRICATION METHOD THEREOF

(71) Applicant: Siliconware Precision Industries Co., Ltd., Taichung (TW)

(72) Inventors: Tso-Chia Chang, Taichung (TW); Cheng-Yu Hsieh, Taichung (TW); Lien-Chen Chiang, Taichung (TW); Fu-Tang Huang, Taichung (TW)

(21) Appl. No.: 14/837,841

(22) Filed: Aug. 27, 2015

(30) Foreign Application Priority Data
Nov. 3, 2014 (TW) 103138011

(51) Int. Cl. H01L 23/498; H01L 21/48; H01L 21/56; H01L 23/31

(52) U.S. Cl. CPC H01L 23/49838; H01L 23/49816; H01L 23/49833; H01L 23/3114; H01L 21/4853; H01L 21/563

(57) ABSTRACT

A package substrate is provided, which includes: a body having opposite first and second surfaces, each having adjacent first and second regions defined thereon; first and second circuit layers formed on the first and second surfaces of the body, respectively; a first insulating layer formed on the first surface of the body and having a plurality of first openings formed in the first insulating layer and positioned in the first and second regions; and a second insulating layer formed on the second surface of the body and having a plurality of second openings formed in the second insulating layer and positioned in the second region. Further, at least a third opening is formed in the second insulating layer and positioned in the first region to reduce the volume of the second insulating layer, thereby facilitating even distribution of thermal stresses through the first and second insulating layers during thermal cycling and hence preventing warpage of the package substrate.

### BACKGROUND OF THE INVENTION

1. Field of the Invention

The present invention relates to package structures and fabrication methods thereof, and more particularly, to a package structure and a fabrication method thereof for improving the product yield.

2. Description of Related Art

Along with the progress of electronic industries, electronic products are developed toward the trend of miniaturization and multi-function. Accordingly, various package types have been developed. To meet the demands of semiconductor devices for high integration, miniaturization and high electrical performance, package on package (PoP) technologies have been developed.

FIG. 1A is a schematic cross-sectional view of a conventional PoP structure 1. Referring to FIG. 1A, the package structure 1 has an upper package 1a and a lower package 1b. The lower package 1b has a chip 11 electrically connected to a first carrier 10 through a plurality of conductive wires 12. The upper package 1a has a plurality of electronic components 16 disposed on a second carrier 13 through a plurality of solder bumps 17. The upper package 1a is stacked on the lower package 1b through a plurality of solder balls 14 that electrically connect the first carrier 10 and the second carrier 13. Further, an encapsulant 15 is formed between the first carrier 10 and the second carrier 13 for encapsulating the chip 11, the conductive wires 12 and the solder balls 14.

Furthermore, the second carrier 13 of the upper package 1a has a carrier body 131 having an upper surface 131a and a lower surface 131b. A circuit layer 132 is formed on the upper surface 131a and the lower surface 131b of the carrier body 131. Further, an upper solder mask layer 133a and a lower solder mask layer 133b are formed on the upper surface 131a and the lower surface 131b of the carrier body 131, respectively, and a plurality of openings 1331, 1332 are formed in the upper and lower solder mask layers 133a, 133b, respectively, so as to expose portions of the circuit layer 132. The solder balls 14 are bonded to the portions of the circuit layer 132 exposed from the openings 1332 of the lower solder mask layer 133b. The solder bumps 17 are bonded to the portions of the circuit layer 132 exposed from the openings 1331 of the upper solder mask layer 133a so as to electrically connect the electronic components 16 to the circuit layer 132.

Since the number of the solder bumps 17 for electrically connecting the electronic components 16 and the circuit layer 132 is significantly greater than the number of the solder balls 14 for electrically connecting the first carrier 10 and the circuit layer 132, the number of the openings 1331 is significantly greater than the number of the openings 1332. As such, referring to FIGS. 1B and 1C, the openings 1331 are distributed substantially throughout the upper solder mask layer 133a, but the lower solder mask layer 133b has a central region A without openings. Accordingly, the area of the upper solder mask layer 133a (having more openings) is far less than the area of the lower solder mask layer 133b (having less openings). As such, thermal stresses cannot be evenly distributed through the upper and lower solder mask layers 133a, 133b during thermal cycling, thereby resulting in an uneven distribution of the thermal stresses on the upper and lower surfaces 131a, 131b of the carrier body 131. Therefore, the second carrier 13 easily warps and consequently the product yield is reduced.

Therefore, how to overcome the above-described drawbacks has become critical.

### SUMMARY OF THE INVENTION

In view of the above-described drawbacks, the present invention provides a package substrate, which comprises: a body having opposite first and second surfaces, each having adjacent first and second regions defined thereon; a first circuit layer formed on the first surface of the body; a second circuit layer formed on the second surface of the body; a first insulating layer formed on the first circuit layer and the first surface of the body, wherein a plurality of first openings are formed in the first insulating layer and positioned in the first and second regions, so as to expose portions of the first circuit layer; and a second insulating layer formed on the second circuit layer and the second surface of the body, wherein a plurality of second openings are formed in the second insulating layer and positioned in the second region , so as to expose portions of the second circuit layer, and at least a third opening is formed in the second insulating layer and positioned in the first region.

The present invention further provides a package structure, which comprises: a package; a plurality of conductive elements formed on and electrically connected to the package; and the above-described package substrate disposed on the conductive elements so as to be stacked on the package, wherein the conductive elements are bonded to the exposed portions of the second circuit layer and electrically connected to the second circuit layer.

The present invention further provides a method for fabricating a package structure, which comprises the steps of: providing a package; and stacking the above-described package substrate on the package, bonding the package to the exposed portions of the second circuit layer through a plurality of conductive elements, and electrically connecting the conductive elements to the second circuit layer.

In the above-described package substrate, package structure and method, the first region can be surrounded by the second region.

In the above-described package substrate, package structure and method, the first insulating layer and the second insulating layer can have substantially the same volume.

In the above-described package substrate, package structure and method, the third opening can have a geometric shape.

In the above-described package structure and method, the package can have a carrier and a first electronic component disposed on and electrically connected to the carrier.

In the above-described package structure and method, a portion of the conductive elements can be positioned in the third opening.

In the above-described package structure and method, a second electronic component can be disposed on the first insulating layer and electrically connected to the first circuit layer.

In the above-described package structure and method, an encapsulant can be formed between the package and the second insulating layer of the package substrate. The encapsulant can further be formed in the third opening.

According to the present invention, at least a third opening is formed in the second insulating layer in the first region so as to reduce the area of the second insulating layer on the second surface of the body of the package substrate, thereby facilitating even distribution of thermal stresses through the first and second insulating layers and hence preventing warpage of the package substrate. Therefore, the present invention improves the product yield.

### BRIEF DESCRIPTION OF DRAWINGS

FIG. 1A is a schematic cross-sectional view of a conventional package structure;

FIG. 1B is a schematic upper view of a second carrier of FIG. 1A;

FIG. 1C is a schematic lower view of the second carrier of FIG. 1A;

FIGS. 2 and 2′ are schematic cross-sectional views of a package substrate of the present invention;

FIG. 2A is a schematic upper view of the package substrate of FIG. 2;

FIG. 2B is a schematic lower view of the package substrate of FIG. 2, wherein FIGS. 2B′ and 2B″ show other embodiments of FIG. 2B; and

FIGS. 3A to 3C are schematic cross-sectional views showing a method for fabricating a package structure according to the present invention, wherein FIGS. 3B′ and 3C′ shows other embodiments of FIGS. 3B and 3C.

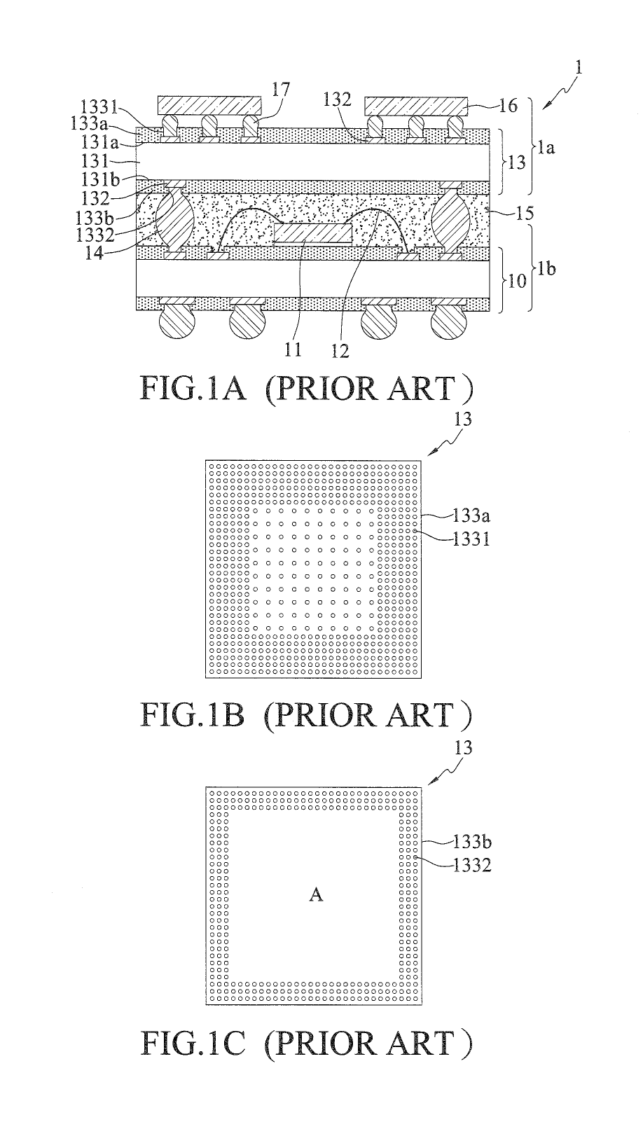

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

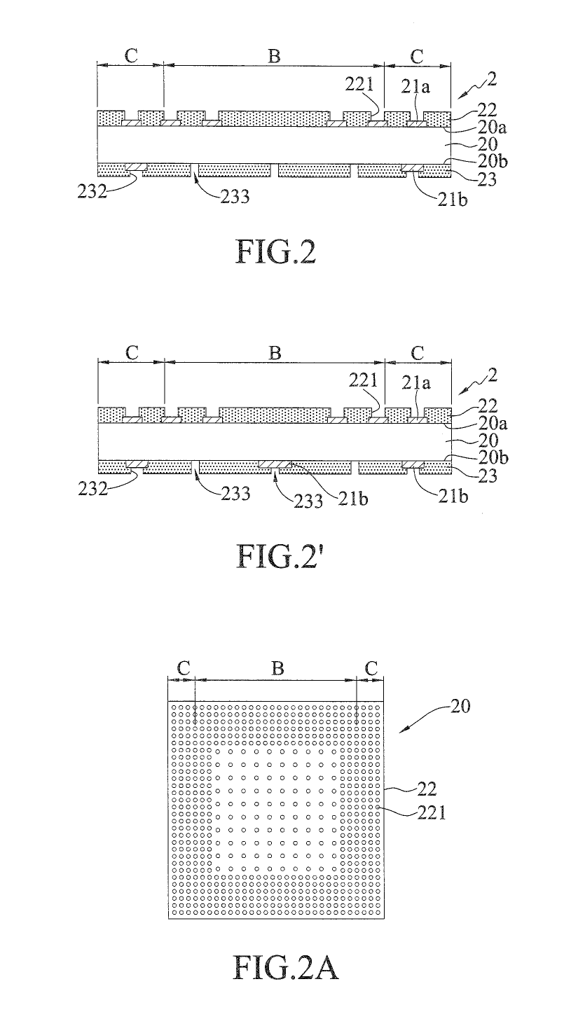

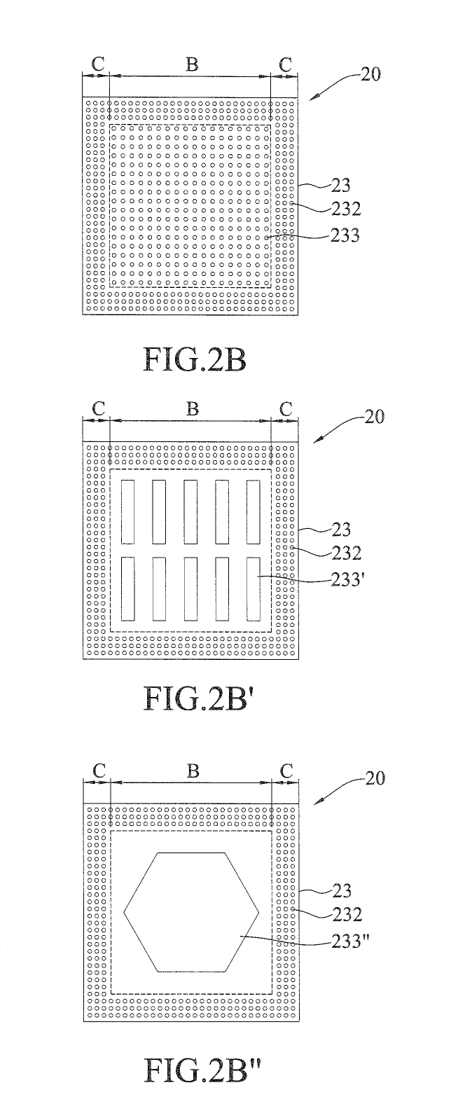

FIG. 2 is a schematic cross-sectional view of a package substrate 2 of the present invention. Referring to FIG. 2, the package substrate 2 has a body 20 having opposite first and second surfaces 20a, 20b. A first region B (e.g., a central region) and a second region C (e.g., a peripheral region) surrounding around and adjacent to the first region B are defined on each of the first and second surfaces 20a, 20b of the body 20.

A first circuit layer 21a is formed on the first surface 20a of the body 20 and a second circuit layer 21b is formed on the second surface 20b of the body 20.

A first insulating layer 22 made of such as solder mask is formed on the first circuit layer 21a and the first surface 20a of the body 20. The first insulating layer 22 has a plurality of first openings 221 formed in the first region B and the second region C , for exposing portions of the first circuit layer 21a, as shown in FIG. 2A.

A second insulating layer 23 made of such as solder mask is formed on the second circuit layer 21b and the second surface 20b of the body 20. The second insulating layer 23 has a plurality of second openings 232 formed in the second region C for exposing portions of the second circuit layer 21b, and a plurality of third openings 233 formed in the first region B, as shown in FIG. 2B.

In the present embodiment, the area of the first surface 20a is the same as the area of the second surface 20b, and the thickness of the first insulating layer 22 is the same as the thickness of the second insulating layer 23. Through formation of the third openings 233, the invention allows the area of the second insulating layer 23 to be the same as the area of the first insulating layer 22. That is, the second insulating layer 23 and the first insulating layer 22 have substantially the same volume.

The third openings 233, 233′, 233″ can have, but not limited to, a geometric shape, for example, a circular shape of FIG. 2B, a rectangular shape of FIG. 2B′ or a polygonal shape 233″ of FIG. 2B″.

In the present embodiment, the third openings 233 expose portions of the second surface 20b of the body 20. In another embodiment, retelling to FIG. 2′, the third openings 233 can further expose portions of the second circuit layer 21b.

Therefore, by forming at least a third opening 233, 233′, 233″ in the second insulating layer 23 in the first region B, the present invention allows the volume of the second insulating layer 23 to be the same as the volume of the first insulating layer 22. As such, thermal stresses can be evenly distributed through the first and second insulating layers 22, 23 during thermal cycling so as to prevent warpage of the package substrate 2.

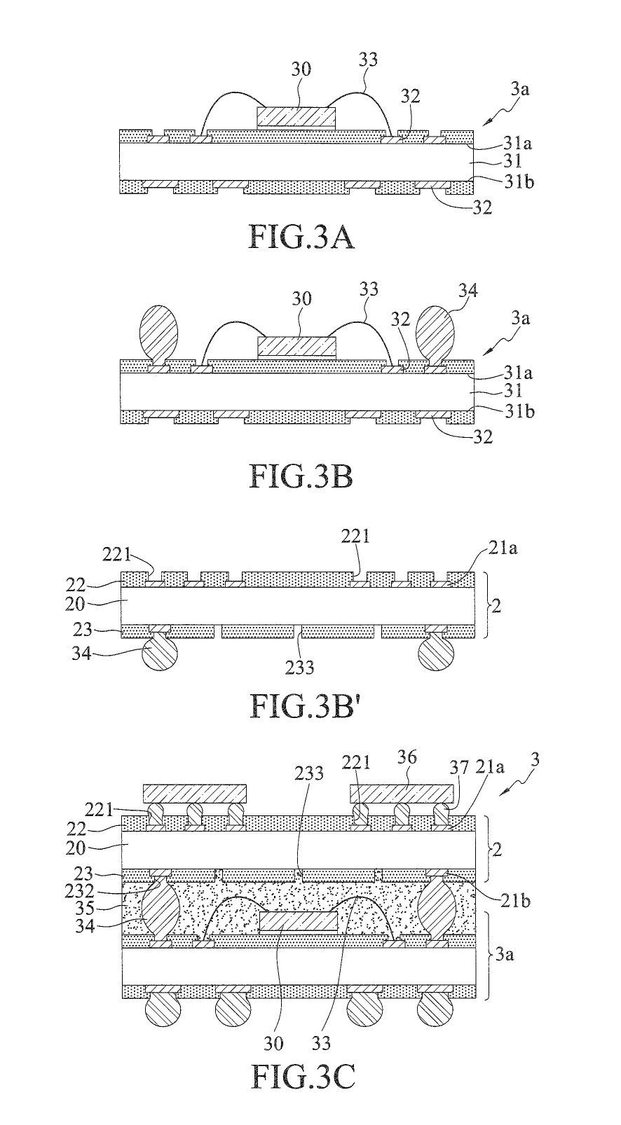

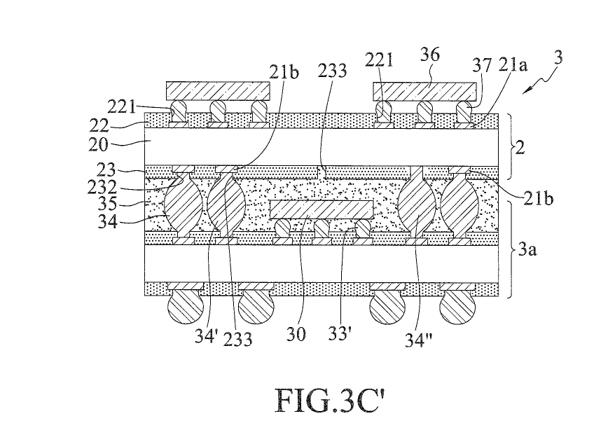

FIGS. 3A and 3B are schematic cross-sectional views showing a method for fabricating a package structure 3 according to the present invention.

Referring to FIG. 3A, a package 3a is provided, which has a carrier 31 and a first electronic component 30 disposed on and electrically connected to the carrier 31.

In the present embodiment, the carrier 31 is a conventional package substrate or a package substrate 2 of the present invention. The carrier 31 has an upper surface 31a and a lower surface 31b. A circuit layer 32 is formed on the upper surface 31a and the lower surface 31b of the carrier 31 and the first electronic component 30 is electrically connected to the circuit layer 32 on the upper surface 31a of the carrier 31 through a plurality of conductive wires 33.

The first electronic component 30 is an active component such as a semiconductor chip, a passive component such as a resistor, a capacitor or an inductor, or a combination thereof.

Referring to FIG. 3B, a plurality of conductive elements 34 are formed on the upper surface 31a of the carrier 31 and electrically connected to the circuit layer 32 of the carrier 31.

In the present embodiment, the conductive elements 34 are solder balls or conductive pillars such as copper pillars.

Referring to FIG. 3C, the package substrate 2 is disposed on the conductive elements 34 so as to be stacked on the package 3a. The conductive elements 34 are bonded to the portions of the second circuit layer 21b exposed from the second openings 232 and electrically connected to the second circuit layer 21b.

Then, an encapsulant 35 is formed between the package 3a and the second insulating layer 23 of the package substrate 2 to encapsulate the first electronic component 30, the conductive wires 33 and the conductive elements 34.

In the present embodiment, the encapsulant 35 is further formed in the third openings 233.

Further, at least a second electronic component 36 can be disposed on the first insulating layer 22, and a plurality of solder bumps 37 or conductive wires (not shown) can be bonded to the portions the first circuit layer 21a exposed from the first openings 221 for electrically connecting the second electronic component 36 and the first circuit layer 21a. The second electronic component 36 is a package, an active component such as a semiconductor chip, a passive component such as a resistor, a capacitor or an inductor, or a combination thereof.

In another embodiment, referring to FIG. 3C′, the first electronic component 30 is electrically connected to the circuit layer 32 through a plurality of conductive bumps 33′.

Referring to FIG. 3C′, the conductive elements 34′, 34″ are further formed in the third openings 233. The conductive elements (for example, the conductive element 34′) can be electrically connected to the second circuit layer 21b, or the conductive elements (for example, the conductive element 34″) can be insulatingly connected to the second circuit layer 21b.

In another embodiment, referring to FIG. 3B′, a plurality of conductive elements 34 are formed on the portions of the second circuit layer 21b exposed from the second openings 232, and the package substrate 2 is stacked on the package 3a through the conductive elements 34.

According to the present invention, since the area of the first insulating layer 22 is the same as the area of the second insulating layer 23, the present invention facilitates even distribution of thermal stresses through the first and second insulating layers 22, 23 during thermal cycling so as to achieve an even distribution of the thermal stresses on the first and second surfaces 20a, 20b of the body 20. Therefore, the present invention prevents warpage of the package substrate 2 and improves the product yield.

The present invention further provides a package structure 3, which has: a package 3a; a plurality of conductive elements 34 formed on and electrically connected to the package 3a; and the package substrate 2 disposed on the conductive elements 34 so as to be stacked on the package 3a, wherein the conductive elements 34 are bonded to the exposed portions of the second circuit layer 21b and electrically connected to the second circuit layer 21b.

The package 3a can have a carrier 31 and a first electronic component 30 disposed on and electrically connected to the carrier 31.

A portion of the conductive elements 34 can be positioned in the third openings 233. The package structure 3 can further have at least a second electronic component 36 disposed on the first insulating layer 22 and electrically connected to the first circuit layer 21a.

The package structure 3 can further have an encapsulant 35 formed between the package 3a and the second insulating layer 23 of the package substrate 2.

The encapsulant 35 can further be formed in the third openings 233.

According to the present invention, at least a third opening is formed in the second insulating layer and positioned in the first region so as to reduce the area of the second insulating layer on the second surface of the body of the package substrate, thereby facilitating even distribution of thermal stresses through the first and second insulating layers and hence preventing warpage of the package substrate. Therefore, the present invention improves the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A package substrate, comprising:
a body having opposite first and second surfaces, wherein each of the first and second surface has adjacent first and second regions defined thereon;
a first circuit layer formed on the first surface of the body;
a second circuit layer formed on the second surface of the body;
a first insulating layer formed on the first circuit layer and the first surface of the body, wherein a plurality of first openings are formed in the first insulating layer and positioned in the first and second regions, so as to expose portions of the first circuit layer; and
a second insulating layer formed on the second circuit layer and the second surface of the body, wherein a plurality of second openings are formed in the second insulating layer and positioned in the second region, so as to expose portions of the second circuit layer, and at least a third opening is formed in the second insulating layer and positioned in the first region.

2. The substrate of claim 1, wherein the first region is surrounded by the second region.

3. The substrate of claim 1, wherein the first insulating layer and the second insulating layer have substantially the same volume.

4. The substrate of claim 1, wherein the third opening has a geometric shape.

5. A package structure, comprising:
a package;
a plurality of conductive elements formed on and electrically connected to the package; and
the package substrate of claim 1 disposed on the conductive elements so as to be stacked on the package, wherein the conductive elements are bonded to the exposed portions of the second circuit layer and electrically connected to the second circuit layer.

6. The structure of claim 5, wherein the first region is surrounded by the second region.

7. The structure of claim 5, wherein the first insulating layer and the second insulating layer have substantially the same volume.

8. The structure of claim 5, wherein the third opening has a geometric shape.

9. The structure of claim 5, wherein the package has a carrier and a first electronic component disposed on and electrically connected to the carrier.

10. The structure of claim 5, wherein a portion of the conductive elements are positioned in the third opening.

11. The structure of claim 5, further comprising a second electronic component disposed on the first insulating layer and electrically connected to the first circuit layer.

12. The structure of claim 5, further comprising an encapsulant formed between the package and the second insulating layer of the package substrate.

13. The structure of claim 12, wherein the encapsulant is further formed in the third opening.

14. A method for fabricating a package structure, comprising the steps of:
providing a package; and
stacking the package substrate of claim 1 on the package, bonding the package to the exposed portions of the second circuit layer through a plurality of conductive elements, and electrically connecting the conductive elements to the second circuit layer.

15. The method of claim 14, wherein the first region is surrounded by the second region.

16. The method of claim 14, wherein the first insulating layer and the second insulating layer have substantially the same volume.

17. The method of claim 14, wherein the third opening has a geometric shape.

18. The method of claim 14, wherein the package has a carrier and a first electronic component disposed on and electrically connected to the carrier.

19. The method of claim 14, wherein a portion of the conductive elements are positioned in the third opening.

20. The method of claim 14, further comprising disposing a second electronic component on the first insulating layer, wherein the second electronic component is electrically connected to the first circuit layer.

21. The method of claim 14, further comprising forming an encapsulant between the package and the second insulating layer of the package substrate.

22. The method of claim 21, wherein the encapsulant is further formed in the third opening.
